(19) United States
(12) Patent Application Publication
(10) Pub. No.: US 2023/0376207 A1
(43) Pub. Date: Nov. 23, 2023

(54) MEMORY DEVICE, MEMORY SYSTEM AND METHOD FOR OPERATING MEMORY SYSTEM

(71) Applicant: SK hynix Inc., Icheon-si (KR)

(72) Inventor: Sung Lae OH, Icheon-si (KR)

(21) Appl. No.: 18/048,081

(22) Filed: Oct. 20, 2022

(30) Foreign Application Priority Data
May 19, 2022 (KR) 10-2022-0061345

(51) Int. Cl. G06F 3/06

(52) U.S. Cl. CPC G06F 3/0613; G06F 3/064; G06F 3/0679

(57) ABSTRACT

A memory device includes a first wafer including a first memory block and a second memory block; and a second wafer arranged in a vertical direction with respect to the first wafer, including a third memory block with a stack number of word lines and a number of strings, each respectively larger than a stack number of word lines and a number of strings of the first memory block and each respectively larger than a stack number of word lines and a number of strings of the second memory block, and sharing, by the third memory block, a plurality of word line drivers with the first memory block and the second memory block.

### CROSS-REFERENCE TO RELATED APPLICATION

The present application claims priority under 35 U.S.C. § 119(a) to Korean Patent Application No. 10-2022-0061345 filed in the Korean Intellectual Property Office on May 19, 2022, which is incorporated herein by reference in its entirety.

### BACKGROUND

### 1. Technical Field

Various embodiments generally relate to a semiconductor technology, and more particularly, to a memory device, a memory system and a method for operating a memory system.

### 2. Related Art

Semiconductor memory devices include volatile memories such as a DRAM and an SRAM and nonvolatile memories such as an EEPROM, an FRAM, a PRAM, an MRAM and a flash memory. The volatile memories lose stored data when power is cut off, but the nonvolatile memories retain stored data even when power is cut off.

Recently, devices increasingly use nonvolatile memories. For example, each of a digital camera, a mobile phone and a solid state disk (SSD) uses a nonvolatile memory as a storage device. Among the nonvolatile memories, the flash memory can function to electrically and collectively erase memory cell data. Thus, the flash memory is widely used as a storage device instead of a hard disk.

### SUMMARY

Various embodiments are directed to a memory device, a memory system and a method for operating a memory system capable of reducing size and improving operation speed.

In an embodiment, a memory device may include: a first wafer including a first memory block and a second memory block; and a second wafer, arranged in a vertical direction with respect to the first wafer, including a third memory block with a stack number of word lines and a number of strings, each respectively larger than a stack number of word lines and a number of strings of the first memory block and each respectively larger than a stack number of word lines and a number of strings of the second memory block, and sharing, by the third memory block, a plurality of word line drivers with the first memory block and the second memory block.

In an embodiment, a memory device may include: a first wafer configured to store hot data, and including a plurality of small blocks; and a second wafer, arranged in a vertical direction with respect to the first wafer and configured to store cold data, including a plurality of large blocks in which a stack number of word lines and a number of strings of a large block are larger than a stack number of word lines and a number of strings of a small block.

In an embodiment, a memory system may include: a memory device including a first wafer including a plurality of small blocks and a second wafer disposed vertically with respect to the first wafer and including a plurality of large blocks in which a stack number of word lines and a number of strings of a large block are larger than a stack number of word lines and a number of strings of a small block; and a controller configured to store hot data of data received from a host, in the first wafer and to store cold data, of data received from a host, in the second wafer.

In an embodiment, a method for operating a memory system may include: receiving data from a host; determining whether the data is hot data or cold data; and storing hot data in a first wafer including a plurality of small blocks, and storing cold data in a second wafer including a plurality of large blocks, each having a stack number of word lines and a number of strings that are larger than a stack number of word lines and a number of strings of a small block.

### BRIEF DESCRIPTION OF THE DRAWINGS

FIG. 1 is a diagram schematically illustrating a memory device in accordance with an embodiment of the present disclosure.

FIG. 2 is a diagram illustrating first to third memory blocks of FIG. 1 and two shared word line drivers.

FIG. 3 is a cross-sectional view illustrating an example of a memory device in accordance with an embodiment of the present disclosure.

FIG. 4 is a cross-sectional view illustrating another example of a memory device in accordance with an embodiment of the present disclosure.

FIG. 5 is a diagram illustrating a memory system in accordance with an embodiment of the present disclosure and an operation in which the memory system stores data.

FIG. 6 is a flowchart illustrating a data storage operation of a memory system in accordance with an embodiment of the present disclosure.

FIG. 7 is a block diagram schematically illustrating a memory system in accordance with an embodiment of the present disclosure.

FIG. 8 is a block diagram schematically illustrating a computing system including a memory system in accordance with embodiments of the present disclosure.

### DETAILED DESCRIPTION

Advantages and features of the disclosure and methods to achieve them will become apparent from the descriptions of exemplary embodiments herein below with reference to the accompanying drawings. However, the present disclosure is not limited to the exemplary embodiments disclosed herein but may be implemented in various different ways. The exemplary embodiments are provided for making the disclosure of the present disclosure thorough and for fully conveying the scope of the present disclosure to those skilled in the art.

Since the figures, dimensions, ratios, angles, numbers of elements given in the drawings to describe embodiments of the disclosure are merely illustrative, the present disclosure is not limited to the illustrated matters. Throughout the specification, like reference numerals refer to like components. In describing the disclosure, when it is determined that the detailed description of the related art may obscure the gist of the disclosure, the detailed description thereof will be omitted. It is to be noticed that the terms “comprising,” “having,” “including” and so on, used in the description and claims, should not be interpreted as being restricted to the means listed thereafter unless specifically stated otherwise. Where an indefinite or definite article, e.g., “a,” “an” or “the,” is used when referring to a singular noun, the article may include a plural of that noun unless specifically stated otherwise. In interpreting elements in embodiments of the disclosure, they should be interpreted as including error margins even without explicit statements.

Also, in describing the components of the disclosure, there may be used terms such as first, second, A, B, (a), and (b). These are solely for the purpose of differentiating one component from another component but do not limit the substances, order, sequence or number of the components. Also, components in embodiments of the disclosure are not limited by these terms. These terms are used to merely distinguish one component from another component. Accordingly, as used herein, a first component may be a second component within the technical spirit of the disclosure.

If a component is described as “connected,” “coupled” or “linked” to another component, it may mean that the component is not only directly “connected,” “coupled” or “linked” but also is indirectly “connected,” “coupled” or “linked” via a third component. In describing positional relationship, such as “an element A on an element B,” “an element A above an element B,” “an element A below an element Bi” and “an element A next to an element B,” one or more other elements may be disposed between the elements A and B unless the term “directly” or “immediately” is explicitly used.

Features of various exemplary embodiments of the disclosure may be coupled, combined or separated partially or totally. Technically various interactions and operations are possible. Various exemplary embodiments can be practiced individually or in combination.

Hereinafter, various examples of embodiments of the disclosure will be described in detail with reference to the accompanying drawings.

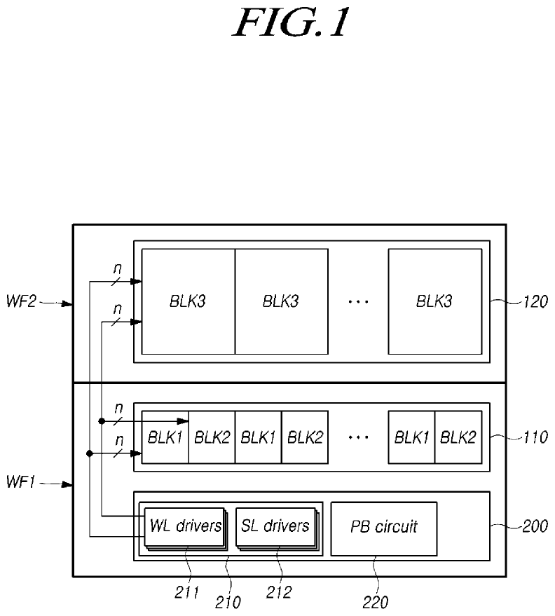

FIG. 1 is a diagram schematically illustrating a memory device in accordance with an embodiment of the present disclosure.

Referring to FIG. 1, the memory device in accordance with the embodiment of the present disclosure may include a first wafer WF1 and a second wafer WF2, which is disposed in a vertical direction with respect to the first wafer WF1.

The memory device according to the embodiment may have a non-monolithic structure. The non-monolithic structure means that the first wafer WF1 and the second wafer WF2 constituting the memory device are separately fabricated from each other and are then coupled to each other by a bonding technique. For example, the first wafer WF1 and the second wafer WF2 may be bonded to each other by hybrid bonding.

The first wafer WF1 may include a first memory cell array 110. The second wafer WF2 may include a second memory cell array 120.

The first memory cell array 110 may include a plurality of small blocks BLK1 and BLK2. The second memory cell array 120 may include a plurality of large blocks BLK3.

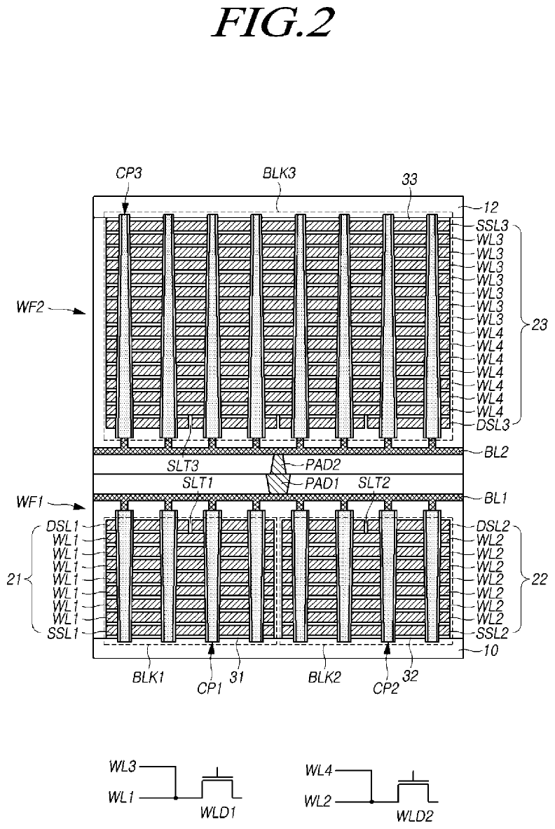

As will be described later with reference to FIG. 2, a small block means a memory block in which the stack number of word lines and the number of strings are small, and a large block means a memory block in which the stack number of word lines and the number of strings are large.

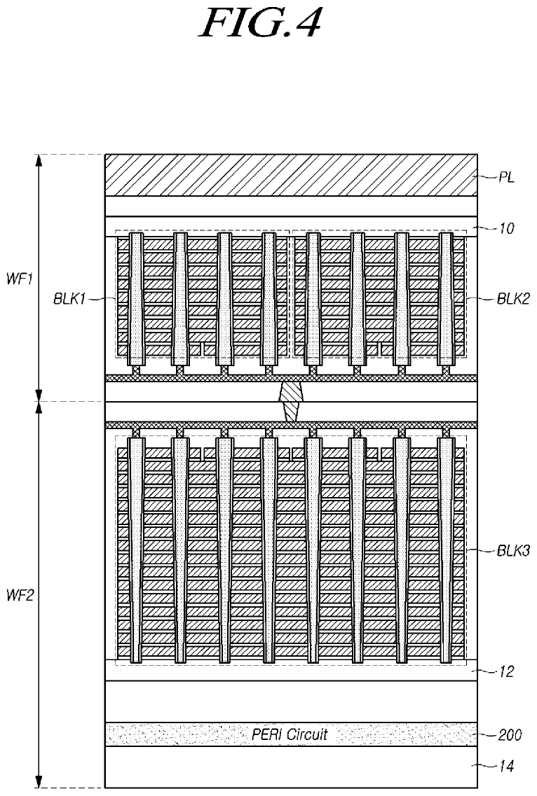

The first wafer WF1 may further include a peripheral circuit 200. Although FIG. 1 illustrates the peripheral circuit 200 configured in the first wafer WF1, the present disclosure is not limited thereto. As will be described later with reference to FIG. 4, the peripheral circuit 200 may be configured in the second wafer WF2. Although not illustrated, the peripheral circuit 200 may be configured in a third wafer that is separate from the first and second wafers WF1 and WF2. The third wafer, including the peripheral circuit 200, may be disposed in the vertical direction with respect to the first and second wafers WF1 and WF2.

The peripheral circuit 200 may include a row decoder 210, a page buffer circuit (PB circuit) 220 and other peripheral circuits (not illustrated). Examples of other peripheral circuits include a control logic, a voltage generator, a column decoder and an input/output (IO) circuit.

The row decoder 210 may include a plurality of word line drivers (WL drivers) 211 and a plurality of select line drivers (SL drivers) 212.

Each of the small blocks BLK1 and BLK2 and the large blocks BLK3 may be coupled to the plurality of word line drivers 211 through a plurality of word lines to be provided with driving signals from the plurality of word line drivers 211. Each of the small blocks BLK1 and BLK2 and the large blocks BLK3 may be coupled to a select line driver 212 through at least one select line to be provided with a select signal from the select line driver 212.

A large block BLK3 may share the plurality of word line drivers 211 with at least two small blocks BLK1 and BLK2. The large block BLK3 may vertically overlap at least two small blocks BLK1 and BLK2, and may share the word line drivers 211 with the small blocks BLK1 and BLK2.

FIG. 1 illustrates two small blocks that share the word line drivers 211 with one large block BLK3. For the sake of convenience in explanation, the large block BLK3 will be defined as a third memory block, and two small blocks BLK1 and BLK2 which share the word line drivers 211 with the third memory block BLK3 will be defined as a first memory block and a second memory block.

An n number of word lines, from among all of the word lines included in the third memory block BLK3, may correspond, on a one-to-one basis, to an n number of word lines included in the first memory block BLK1. Each of the n number of word lines of the third memory block BLK3 may be coupled in common to one word line driver that corresponds to one of the n number of word lines of the first memory block BLK1.

An n number of word lines, from among all of the word lines included in the third memory block BLK3, that do not share a word line driver with the first memory block BLK1, may have a one-to-one correspondence to an n number of word lines included in the second memory block BLK2. Each of the n number of word lines of the third memory block BLK3 may be coupled in common to one word line driver that corresponds to one of the n number of word lines of the second memory block BLK2.

FIG. 2 is a diagram illustrating first to third memory blocks of FIG. 1 and two shared word line drivers.

Referring to FIG. 2, the first memory block BLK1 and the second memory block BLK2 may be disposed adjacent to each other on a first source plate 10 of the first wafer WF1.

The first memory block BLK1 may include a plurality of first electrode layers 21 and a plurality of first interlayer dielectric layers 31, which are alternately stacked in the vertical direction, and a plurality of first cell plugs CP1 that extend to the first source plate 10 by vertically passing through the plurality of first electrode layers 21 and the plurality of first interlayer dielectric layers 31.

At least one of the plurality of first electrode layers 21 from the lowermost layer of the stack may constitute a first source select line SSL1. At least one of the plurality of first electrode layers 21 from the uppermost layer of the stack may constitute a first drain select line DSL1. The first electrode layers 21 between the first source select line SSL1 and the first drain select line DSL1 may constitute first word lines WL1. The first drain select line DSL1 may be divided into units smaller than a memory block by a first slit SLT1, which is formed in the first drain select line DSL1.

A source select transistor may be configured at a portion or region where the first source select line SSL1 surrounds the first cell plug CP1. Memory cells may be configured at portions or regions where the first word lines WL1 surround the first cell plug CP1. A drain select transistor may be configured at a portion or region where the first drain select line DSL1 surrounds the first cell plug CP1. A string is configured by the source select transistor, the memory cells and the drain select transistor that are vertically disposed along one first cell plug CP1. The number of strings in the first memory block BLK1 may be the same as the number of the first cell plugs CP1.

The second memory block BLK2 may include a plurality of second electrode layers 22 and a plurality of second interlayer dielectric layers 32, which are alternately stacked on the first source plate 10, and a plurality of second cell plugs CP2 that extend to the first source plate 10 by vertically passing through the plurality of second electrode layers 22 and the plurality of second interlayer dielectric layers 32.

At least one of the plurality of second electrode layers 22 from the lowermost layer of the stack may constitute a second source select line SSL2. At least one of the plurality of second electrode layers 22 from the uppermost layer of the stack may constitute a second drain select line DSL2. The second electrode layers 22 between the second source select line SSL2 and the second drain select line DSL2 may constitute second word lines WL2. A second slit SLT2 is formed in the second drain select line DSL2 so that the second drain select line DSL2 may be divided into units smaller than a memory block.

The number of second word lines WL2 included in the second memory block BLK2 may be the same as the number of first word lines WL1 included in the first memory block BLK1.

The second memory block BLK2 may include the same number of strings as the number of the second cell plugs CP2. The number of second cell plugs CP2 included in the second memory block BLK2 may be the same as the number of first cell plugs CP1 included in the first memory block BLK1. The second memory block BLK2 may have the same number of strings as the first memory block BLK1.

The third memory block BLK3 may include a plurality of third electrode layers 23 and a plurality of third interlayer dielectric layers 33, which are alternately stacked on a second source plate 12, and a plurality of third cell plugs CP3, which extend to the second source plate 12 by vertically passing through the plurality of third electrode layers 23 and the plurality of third interlayer dielectric layers 33.

At least one of the plurality of third electrode layers 23 from the uppermost layer of the stack may constitute a third source select line SSL3. At least one of the plurality of third electrode layers 23 from the lowermost layer of the stack may constitute a third drain select line DSL3. The third electrode layers 23 between the third source select line SSL3 and the third drain select line DSL3 may constitute word lines WL3 and WL4. Third slits SLT3 are formed in the third drain select line DSL3 that divide the third drain select line DSL3 into units smaller than a memory block.

The third memory block BLK3 may include the same number of strings as the number of the third cell plugs CP3. The number of the third cell plugs CP3 included in the third memory block BLK3 may be larger than the number of the first cell plugs CP1 included in the first memory block BLK1. The number of the third cell plugs CP3 included in the third memory block BLK3 may be larger than the number of the second cell plugs CP2 included in the second memory block BLK2. The third memory block BLK3 may have a larger number of strings as compared to the first memory block BLK1 and as compared to the second memory block BLK2.

For example, the number of the third cell plugs CP3 of the third memory block BLK3 may be twice the number of the first cell plugs CP1 of the first memory block BLK1, and may be twice the number of the second cell plugs CP2 of the second memory block BLK2. In this case, the number of strings of the third memory block BLK3 is two times the number of strings of the first memory block BLK1 and two times the number of strings of the second memory block BLK2.

The number of the word lines WL3 and WL4 of the third memory block BLK3 may be larger than the number of the first word lines WL1 of the first memory block BLK1 and may be larger than the number of the second word lines WL2 of the second memory block BLK2. For example, the number of the word lines WL3 and WL4 of the third memory block BLK3 may be two times the number of the first word lines WL1 of the first memory block BLK1 and may be two times the number of the second word lines WL2 of the second memory block BLK2.

The word lines WL3 and WL4 of the third memory block BLK3 may include a plurality of third word lines WL3 and a plurality of fourth word lines WL4 that are stacked under the plurality of third word lines WL3.

The plurality of third word lines WL3 may correspond to the plurality of first word lines WL1, respectively, and may each be coupled to one word line driver WLD1 in common with a corresponding first word line WL1 to share the one word line driver WLD1. The plurality of fourth word lines WL4 may correspond to the plurality of second word lines WL2, respectively, and may each be coupled to one word line driver WLD2 in common with a corresponding second word line WL2 to share the one word line driver WLD2.

Since the third memory block BLK3 shares word line drivers with both the first memory block BLK1 and the second memory block BLK2, the number of word line drivers may be reduced as compared to a conventional device in which word line drivers are not shared.

Although not illustrated in the drawing, the first and second memory blocks BLK1 and BLK2 do not share a select line driver with the third memory block BLK3. In detail, the first source select line SSL1 and the second source select line SSL2 are coupled to different select line drivers from the third source select line SSL3. Similarly, the first drain select line DSL1 and the second drain select line DSL2 are coupled to different select line drivers from the third drain select line DSL3.

As described above, the first and second memory blocks BLK1 and BLK2 and the third memory block BLK3 are configured on different source plates. That is to say, the first and second memory blocks BLK1 and BLK2 do not share a source plate with the third memory block BLK3.

Because the first and second memory blocks BLK1 and BLK2 share word line drivers with the third memory block BLK3, when the third memory block BLK3 is selected to perform a specific operation (e.g., a program/read/erase operation), driving signals for controlling the word lines WL3 and WL4 of the third memory block BLK3 may be applied to the word lines WL1 and WL2 of unselected first and second memory blocks BLK1 and BLK2.

Because the first and second memory blocks BLK1 and BLK2 do not share a select line driver and a source plate with the third memory block BLK3, even though the driving signals for controlling the word lines WL3 and WL4 of the third memory block BLK3 are applied to the word lines WL1 and WL2 of the unselected first and second memory blocks BLK1 and BLK2, the first and second memory blocks BLK1 and BLK2 will not be programmed/read/erased.

Accordingly, the operation of the third memory block BLK3 may be controlled independently of the first and second memory blocks BLK1 and BLK2. The third memory block BLK3 may be programmed/read/erased independently of the first and second memory blocks BLK1 and BLK2.

A first bit line BL1 may be configured over the first and second memory blocks BLK1 and BLK2 in the first wafer WF1. A second bit line BL2 may be configured below the third memory block BLK3 in the second wafer WF2. FIG. 2 is a cross-sectional view taken in the extension direction of a bit line. Although FIG. 2 illustrates only one first bit line BL1 and only one second bit line BL2, it is to be understood that a plurality of first bit lines BL1 and a plurality of second bit lines BL2 are arranged in a direction perpendicular to the plane of the cross-section in FIG. 2.

The first bit line BL1 may be coupled to the first cell plugs CP1 and the second cell plugs CP2 through underlying contacts. The second bit line BL2 may be coupled to the third cell plugs CP3 through overlying contacts.

A first bonding pad PAD1 may be configured on the bonding surface of the first wafer WF1, and a second bonding pad PAD2 may be configured on the bonding surface of the second wafer WF2. For the sake of simplicity in illustration, FIG. 2 illustrates only one first bonding pad PAD1, which is coupled to the first bit line BL1, and only one second bonding pad PAD2, which is coupled to the second bit line BL2. Although not illustrated, a plurality of first bonding pads PAD1 are configured on the bonding surface of the first wafer WF1, and a plurality of second bonding pads PAD2 are configured on the bonding surface of the second wafer WF2.

The first bonding pad PAD1, which is coupled to the first bit line BL1, and the second bonding pad PAD2, which is coupled to the second bit line BL2, may be bonded to each other, and the first bit line BL1 and the second bit line BL2 may be coupled to each other through the first and second bonding pads PAD1 and PAD2 and the contacts. The first bit line BL1 and the second bit line BL2 that are coupled to each other may be coupled in common to one page buffer to share the one page buffer.

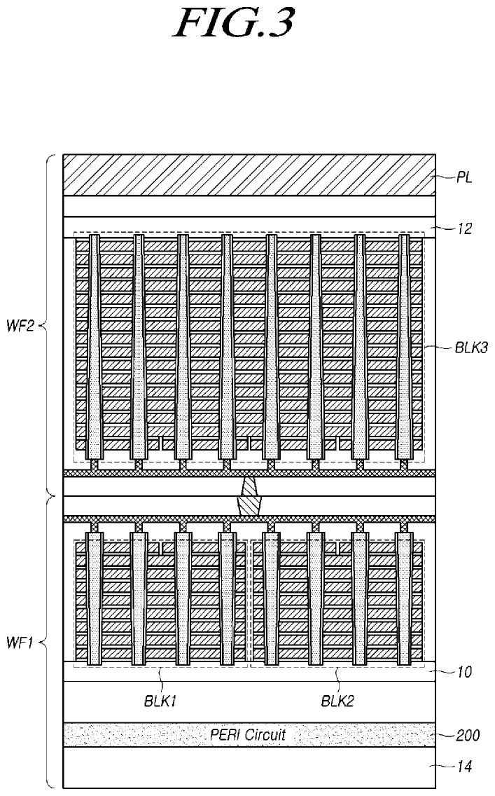

FIG. 3 is a cross-sectional view illustrating an example of a memory device in accordance with an embodiment of the present disclosure.

Referring to FIG. 3, a first wafer WF1 may include a substrate 14, which vertically overlaps first and second memory blocks BLK1 and BLK2, and a peripheral circuit 200, which is configured on a substrate 14. For example, the substrate 14 may be configured below a first source plate 10, and the peripheral circuit 200 may be configured between the substrate 14 and the first source plate 10. As described above with reference to FIG. 1, the peripheral circuit 200 may include word line drivers and select line drivers.

A second wafer WF2 may further include a pad layer PL, which is disposed over a second source plate 12. Although not illustrated, a protective layer may be configured on the pad layer PL. The protective layer may have an opening that exposes a portion of the pad layer PL. The portion of the pad layer PL that is exposed by the opening may configure an external coupling pad for electrical coupling with an external device, such as for example, a memory controller.

FIG. 4 is a cross-sectional view illustrating another example of a memory device in accordance with an embodiment of the present disclosure.

Referring to FIG. 4, a memory device according to an embodiment of the present disclosure differs from the embodiment described above with reference to FIG. 3 in that the peripheral circuit 200 is included in the second wafer WF2 and a pad layer PL is included in the first wafer WF1.

In detail, the second wafer WF2 may include a substrate 14 that vertically overlaps the third memory block BLK3 and the peripheral circuit 200, which is configured on the substrate 14. For example, the substrate 14 may be disposed below the second source plate 12, and the peripheral circuit 200 may be configured between the substrate 14 and the second source plate 12.

The first wafer WF1 may further include the pad layer PL that is disposed over the first source plate 10. Although not illustrated, a protective layer may be configured on the pad layer PL. The protective layer may have an opening that exposes a portion of the pad layer PL. The portion of the pad layer PL that is exposed by the opening may configure an external coupling pad for electrical coupling with an external device, such as for example, a memory controller.

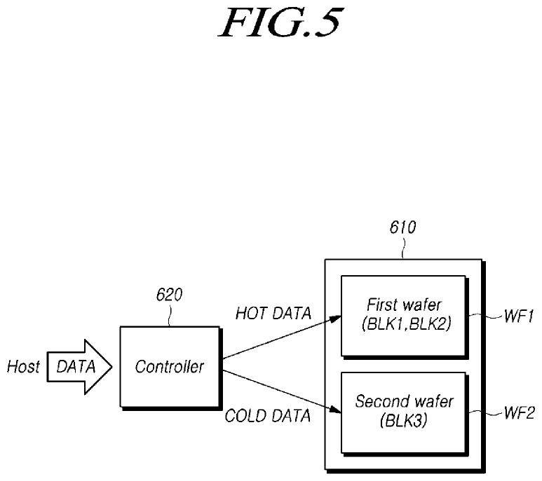

FIG. 5 is a diagram illustrating a memory system in accordance with an embodiment of the present disclosure and an operation in which the memory system stores data.

Referring to FIG. 5, a memory system in accordance with an embodiment of the present disclosure may include a nonvolatile memory device 610 and a controller 620.

The data storage operation of the memory system may be applied when a memory device described above with reference to FIGS. 1 to 4 is used as the nonvolatile memory device 610.

In other words, a first wafer WF1 of the nonvolatile memory device 610 may include small blocks BLK1 and BLK2, in each of which the stack number of word lines and the number of strings are relatively small, and a second wafer WF2 of the nonvolatile memory device 610 may include large blocks BLK3 in each of which the stack number of word lines and the number of strings are relatively large.

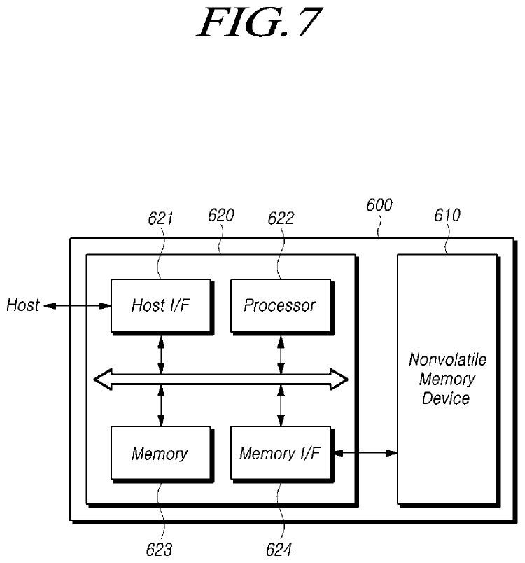

As will be described below with reference to FIG. 7, the controller 620 may include a processor and a memory. The processor may process a request transmitted from a host. In order to process the request transmitted from the host, the processor may drive firmware and control functional blocks inside the controller 620 and the nonvolatile memory device 610. The memory may store the firmware driven by the processor. The memory may store data necessary for driving the firmware, for example, metadata. The memory may include a data buffer for temporarily storing write data to be transmitted from the host to the nonvolatile memory device 610 or read data to be transmitted from the nonvolatile memory device 610 to the host. The memory may receive and store map data from the nonvolatile memory device 610 when the memory system is booted. The map data may include first map data including logical/physical (L2P: logical to physical) information on memory blocks in which data is stored, and second map data including physical/logical (P2L: physical to logical) information.

The controller 620 may determine whether data received from the host is hot data or cold data. Hot data may mean data with a high read frequency, and cold data may mean data with a relatively low read frequency.

On the basis of a hot data or cold data determination result, the controller 620 may store the data received from the host in any one of the first wafer WF1 and the second wafer WF2. For example, the controller 620 may store the data received from the host in the first wafer WF1 upon determining that the data is hot data, and may store the data received from the host in the second wafer WF2 upon determining that the data is cold data.

For example, upon determining that the data received from the host is hot data, the controller 620 may sequentially allocate the small blocks BLK1 and BLK2 of the first wafer WF1 as a target memory block for data storage through a round robin scheduling algorithm, and upon determining that the data received from the host is cold data, the controller 620 may sequentially allocate the large blocks BLK3 of the second wafer WF2 as a target memory block for data storage through the round robin scheduling algorithm. The controller 620 may store the data received from the host in the target memory block.

The controller 620 may update the map data each time data provided from the host is stored in a memory block. Namely, the first map data including logical/physical (L2P) information and the second map data including physical/logical (P2L) information on a memory block in which data is stored may be updated.

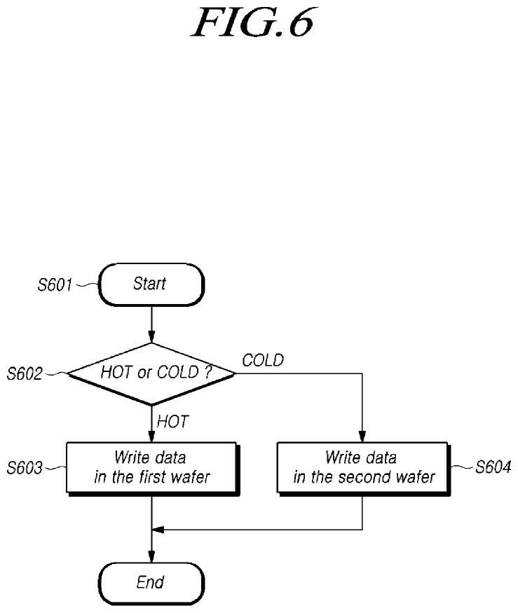

FIG. 6 is a flowchart illustrating a data storage operation of a memory system in accordance with an embodiment of the present disclosure.

Referring to FIGS. 5 and 6, first, a write operation is started by receiving data together with a write command from the host (S601).

The controller 620 determines that the property of the data received from the host, i.e., whether the data is hot data or cold data (S602).

When it is determined that the data received from the host has a hot property, the controller 620 stores the data in the first wafer WF1 (S603). The controller 620 may store the hot data by sequentially allocating small blocks BLK1 and BLK2 included in the first wafer WF1 as target memory blocks for storing the hot data through the round robin scheduling algorithm.

For example, the controller 620 allocates one of the small blocks BLK1 and BLK2 of the first wafer WF1 as a target memory block, and stores hot data received from the host in the target memory block. If all pages included in the target memory block are sequentially selected by once through storage operation, it may be considered that the hot data is stored in the target memory block. Therefore, when all pages included in the target memory block have been checked and found to have been selected by once, another one of the small blocks BLK1 and BLK2 of the first wafer WF1 is allocated as a new target memory block to store the hot data received from the host, and subsequently, the hot data received from the host is stored in the new target memory block.

When it is determined that the data received from the host has cold property, the controller 620 stores the data in the second wafer WF2 (S604). The controller 620 may store the cold data by sequentially allocating large blocks BLK3 of the second wafer WF2 as target memory blocks for storing the cold data through the round robin scheduling algorithm.

For example, the controller 620 allocates one of the large blocks BLK3 of the second wafer WF2 as a target memory block and stores cold data received from the host in the target memory block. If all pages included in the target memory block are sequentially selected by once through a storage operation, then it may be considered that the cold data is stored in the target memory block. Therefore, when all pages included in the target memory block are found to have been selected by once, another one of the large blocks BLK3 of the second wafer WF2 is allocated as a new target memory block to store the cold data received from the host, and the cold data received from the host is stored in the new target memory block.

As is generally known, the data reliability of a memory block degrades as read operations are repeatedly performed. For example, a memory block in which 100K reads are performed has a higher possibility of error in stored data than a memory block in which 10K read operations are performed. As such, in order to prevent the degradation of data reliability (or a read disturbance) due to repetition of read operations, a memory device migrates data written in a memory block, in which a read operation is performed at least a predetermined number of times, to another memory block. The memory device then performs an erase operation for the memory block in which a read operation is performed at least the predetermined number of times to initialize the memory block. Such an operation is referred to as read reclaim.

However, when an erase operation is frequently performed for read reclaim, since the erase operation takes a lot of time, the operation speed of a memory device may become slow. A memory block in which hot data with a high read frequency is stored is more likely to have an error in data than a memory block in which cold data with a low read frequency is stored, and thus, has a memory block with hot data experiences a shorter period of time between data storage and read reclaim. A frequent read reclaim operation for memory blocks in which hot data is stored may serve as a factor that decreases the operation speed of the memory device.

If the size of a memory block is reduced, then the amount of time required for an erase operation may be reduced. However, if the number of memory blocks increases, then the number of word lines increases in proportion to the increased number of memory blocks, and the number of word line drivers for controlling the word lines increases. Thus, as the occupation area of the word line drivers increases, the size of a memory device may increase.

According to embodiments of the present disclosure, by configuring the memory blocks BLK1 and BLK2 of the first wafer WF1 to have a smaller stack number of word lines and a smaller number of strings (as small blocks); by configuring the memory blocks BLK3 of the second wafer WF2 to have a larger stack number of word lines and a larger number of strings (as large blocks); and by configuring the memory block BLK3 included in the second wafer WF2 to share word line drivers with at least two memory blocks BLK1 and BLK2 included in the first wafer WF1, the number of word line drivers may be reduced, and an area occupied by the word line drivers may be reduced, whereby it is possible to reduce the size of a memory device.

Since the stack number of word lines and the number of strings are smaller, the memory blocks BLK1 and BLK2 of the first wafer WF1 have a shorter erase time as compared to the memory blocks BLK3 of the second wafer WF2. According to embodiments of the present disclosure, by storing hot data in the memory blocks BLK1 and BLK2 of the first wafer WF1 and storing cold data in the memory blocks BLK3 of the second wafer WF2, an erase time of a memory block in which hot data requiring frequent read reclaim is stored may be reduced, whereby it is possible to improve the operation speed of a memory device.

FIG. 7 is a block diagram schematically illustrating a memory system in accordance with an embodiment of the present disclosure.

Referring to FIG. 7, a memory system 600 may store data to be accessed by a host such as a mobile phone, an MP3 player, a laptop computer, a desktop computer, a game player, a TV, an in-vehicle infotainment system, and so forth.

The memory system 600 may be manufactured as any one of various kinds of storage devices according to the protocol of an interface that is electrically coupled to the host. For example, the memory system 600 may be configured as any one of various kinds of storage devices such as a solid state drive, a multimedia card in the form of an MMC, an eMMC, an RS-MMC and a micro-MMC, a secure digital card in the form of an SD, a mini-SD and a micro-SD, a universal serial bus (USB) storage device, a universal flash storage (UFS) device, a Personal Computer Memory Card International Association (PCMCIA) card type storage device, a peripheral component interconnection (PCI) card type storage device, a PCI express (PCI-E) card type storage device, a compact flash (CF) card, a smart media card, a memory stick, and so forth.

The memory system 600 may be manufactured as any one among various kinds of package types. For example, the memory system 600 may be manufactured as any one of various kinds of package types such as a package-on-package (POP), a system-in-package (SIP), a system-on-chip (SOC), a multi-chip package (MCP), a chip-on-board (COB), a wafer-level fabricated package (WFP) and a wafer-level stack package (WSP).

The memory system 600 may include a nonvolatile memory device 610 and a controller 620.

The nonvolatile memory device 610 may operate as a storage medium of the memory system 600. The nonvolatile memory device 610 may be configured by any one of various types of nonvolatile memory devices such as a NAND flash memory device, a NOR flash memory device, a ferroelectric random access memory (FRAM) using a ferroelectric capacitor, a magnetic random access memory (MRAM) using a tunneling magneto-resistive (TMR) layer, a phase change random access memory (PRAM) using a chalcogenide alloy, and a resistive random access memory (RERAM) using a transition metal compound, depending on memory cells.

The nonvolatile memory device 610 may include memory devices according to embodiments of the present disclosure previously described with reference to FIGS. 1 to 5. While FIG. 7 illustrates that the memory system 600 includes one nonvolatile memory device 610, this is only for the sake of convenience in explanation, and the memory system 600 may include a plurality of nonvolatile memory devices. The present disclosure may be applied the same to the memory system 600 including a plurality of nonvolatile memory devices. The nonvolatile memory device 610 may include memory devices according to the embodiments of the present disclosure.

The controller 620 may control general operations of the memory system 600 through driving of firmware or software loaded in a memory 623. The controller 620 may decode and drive a code type instruction or algorithm such as firmware or software. The controller 620 may be implemented in the form of hardware or in a combined form of hardware and software.

The controller 620 may include a host interface 621, a processor 622, the memory 623 and a memory interface 624. Although not illustrated in FIG. 7, the controller 620 may further include an ECC (error correction code) engine that generates a parity by ECC-encoding write data provided from the host and ECC-decodes read data, read from the nonvolatile memory device 610, by using the parity.

The host interface 621 may interface the host and the memory system 600 in correspondence to the protocol of the host. For example, the host interface 621 may communicate with the host through any one of universal serial bus (USB), universal flash storage (UFS), multimedia card (MMC), parallel advanced technology attachment (PATA), serial advanced technology attachment (SATA), small computer system interface (SCSI), serial attached SCSI (SAS), peripheral component interconnection (PCI) and PCI express (PCI-E) protocols.

The processor 622 may be configured by a micro control unit (MCU) or a central processing unit (CPU). The processor 622 may process a request transmitted from the host. In order to process a request transmitted from the host, the processor 622 may drive a code type instruction or algorithm, that is, firmware, loaded in the memory 623, and may control the internal function blocks such as the host interface 621, the memory 623 and the memory interface 624 and the nonvolatile memory device 610.

The processor 622 may generate control signals for controlling the operation of the nonvolatile memory device 610, on the basis of requests transmitted from the host, and may provide the generated control signals to the nonvolatile memory device 610 through the memory interface 624.

The memory 623 may be configured by a random access memory such as a dynamic random access memory (DRAM) or a static random access memory (SRAM). The memory 623 may store firmware to be driven by the processor 622. Also, the memory 623 may store data necessary for driving the firmware, for example, metadata. Namely, the memory 623 may operate as a working memory of the processor 622.

The memory 623 may be configured to include a data buffer for temporarily storing write data to be transmitted from the host to the nonvolatile memory device 610 or read data to be transmitted from the nonvolatile memory device 610 to the host. In other words, the memory 623 may operate as a buffer memory. The memory 623 may receive and store map data from the nonvolatile memory device 610 when the memory system 600 is booted.

The memory interface 624 may control the nonvolatile memory device 610 under the control of the processor 622. The memory interface 624 may also be referred to as a memory controller. The memory interface 624 may provide control signals to the nonvolatile memory device 610. The control signals may include a command, an address, an operation control signal and so forth for controlling the nonvolatile memory device 610. The memory interface 624 may provide data, stored in the data buffer, to the nonvolatile memory device 610, or may store data, transmitted from the nonvolatile memory device 610, in the data buffer.

The controller 620 may further include a map cache (not illustrated) that caches map data referred to by the processor 622 among map data stored in the memory 623.

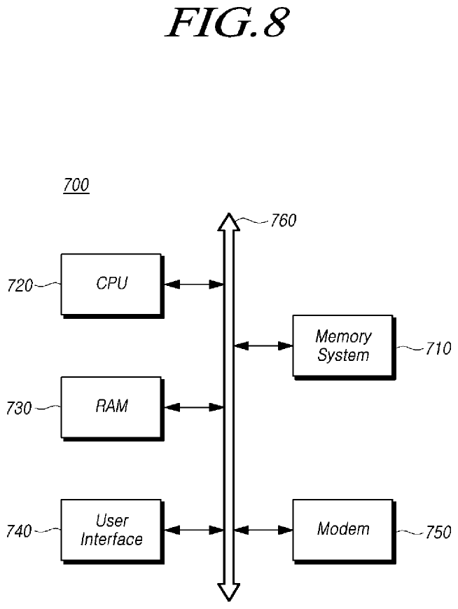

FIG. 8 is a block diagram schematically illustrating a computing system including a memory system in accordance with embodiments of the disclosure.

Referring to FIG. 8, a computing system 700 in accordance with an embodiment may include a memory system 710, a microprocessor (CPU) 720, a RAM 730, a user interface 740 and a modem 750 such as a baseband chipset, which are electrically coupled to a system bus 760. In the case where the computing system 700 in accordance with the embodiment is a mobile device, a battery (not shown) for supplying the operating voltage of the computing system 700 may be additionally provided. Although not shown in the drawing, it is obvious to a person skilled in the art to which the embodiment pertains that the computing system 700 in accordance with the embodiment may be additionally provided with an application chipset, a camera image processor (CIS), a mobile DRAM, and so on. The memory system 710 may configure, for example, an SSD (solid state drive/disk) that uses a nonvolatile memory to store data. Otherwise, the memory system 710 may be provided as a fusion flash memory (for example, a OneNAND flash memory).

Although the detailed description of the present invention described above has been described with reference to the embodiments of the present invention, those skilled in the art or those having ordinary skill in the art will understand that the present invention can be variously modified and changed without departing from the spirit and scope of the present invention described in the claims to be described later.

What is claimed is:

1. A memory device comprising:
a first wafer including a first memory block and a second memory block; and
a second wafer, arranged in a vertical direction with respect to the first wafer, including a third memory block with a stack number of word lines and a number of strings, each respectively larger than a stack number of word lines and a number of strings of the first memory block and each respectively larger than a stack number of word lines and a number of strings of the second memory block, and sharing, by the third memory block, a plurality of word line drivers with the first memory block and the second memory block.

2. The memory device according to claim 1, wherein the word line drivers are included in the first wafer and configured on a substrate, and the word line drivers vertically overlap the first and second memory blocks.

3. The memory device according to claim 1, wherein the word line drivers are included in the second wafer and configured on a substrate, and the word line drivers vertically overlap the third memory block.

4. The memory device according to claim 1, wherein
the first wafer further includes a first bit line that is coupled to the first and second memory blocks,
the second wafer further includes a second bit line that is coupled to the third memory block, and
the first bit line and the second bit line are coupled in common to one page buffer.

5. The memory device according to claim 1, wherein the third memory block vertically overlaps the first memory block and the second memory block.

6. The memory device according to claim 1, wherein the third memory block does not share a select line driver with the first memory block and does not share a select line driver with the second memory block.

7. The memory device according to claim 1, wherein the third memory block is programmed, read, and erased independent of the first memory block and the second memory block.

8. The memory device according to claim 1, wherein the first wafer and the second wafer are bonded to each other.

9. The memory device according to claim 1, wherein word lines of the third memory block that share word line drivers with the first memory block are stacked over word lines of the third memory block that share word line drivers with the second memory block.

10. A memory device comprising:
a first wafer configured to store hot data, and including a plurality of small blocks; and
a second wafer, arranged in a vertical direction with respect to the first wafer and configured to store cold data, including a plurality of large blocks in which a stack number of word lines and a number of strings of a large block are larger than a stack number of word lines and a number of strings of a small block.

11. The memory device according to claim 10, wherein each of the plurality of large blocks vertically overlaps at least two small blocks.

12. The memory device according to claim 10, wherein the first wafer and the second wafer are bonded to each other.

13. A memory system comprising:
a memory device including a first wafer including a plurality of small blocks and a second wafer disposed vertically with respect to the first wafer and including a plurality of large blocks in which a stack number of word lines and a number of strings of a large block are larger than a stack number of word lines and a number of strings of a small block; and
a controller configured to store hot data, of data received from a host, in the first wafer and to store cold data, of data received from a host, in the second wafer.

14. The memory system according to claim 13, wherein each of the plurality of large blocks shares word line drivers with at least two of the plurality of small blocks.

15. The memory system according to claim 14, wherein the each of the plurality of large blocks vertically overlaps the at least two of the plurality of small blocks.

16. The memory system according to claim 13, wherein the word line drivers are included in the first wafer, configured on a substrate, and arranged to vertically overlap the plurality of small blocks.

17. The memory system according to claim 13, wherein the word line drivers are included in the second wafer, are configured on a substrate, and are arranged to vertically overlap the plurality of large blocks.

18. The memory system according to claim 13, wherein the first wafer and the second wafer are bonded to each other.
